(19) United States
(12) Patent Application Publication
(10) Pub. No.: US 2026/0161867 A1
(43) Pub. Date: Jun. 11, 2026

(54) DISPLAYING MNEMONICS AND SYMBOLIC NAMES OF SIGNALS IN RTL CODE BLOCKS

(71) Applicant: Singularity Dynamics Private Limited, Bangalore (IN)

(72) Inventor: Harish Kumar, Bangalore (IN)

(21) Appl. No.: 19/416,094

(22) Filed: Dec. 11, 2025

Related U.S. Application Data
(60) Provisional application No. 63/730,500, filed on Dec. 11, 2024.

(51) Int. Cl. G06F 30/33

(52) U.S. Cl. CPC G06F 30/33

(57) ABSTRACT

Disclosed subject matter relates to verification and debugging tool and method for displaying mnemonics and symbolic names of signals in Register Transfer Level (RTL) code blocks. Verification and debugging tool includes input interface configured to receive RTL code in Hardware Description Language (HDL). Further, verification and debugging tool includes RTL parser configured to parse RTL code, and generate abstract syntax tree representing syntactic structure of RTL code. Thereafter, convert abstract syntax tree into RTL directed graph. Furthermore, examine one or more signal values of RTL code blocks, determine whether signal value corresponds to instruction or data packet, assign instruction mnemonic to signal value when signal represents instruction, and assign unique symbolic name to signal value when signal represents data packet. Finally, display RTL directed graph along with assigned instruction mnemonics and symbolic names.

### CROSS-REFERENCE TO RELATED APPLICATIONS

The present application claims the benefit of priority to U.S. Provisional Application No. 63/730,500, filed on December 11, 2024; the contents of which are hereby incorporated by reference herein in their entirety.

### TECHNICAL FIELD

The present disclosure relates to electronic design. Particularly, the present disclosure relates to a displaying mnemonics and symbolic names of signals in Register Transfer Level (RTL) code blocks.

### BACKGROUND

Modern electronic design is typically performed with Computer-Aided Design (CAD) tools or Electronic Design Automation (EDA) systems. To design an Integrated Circuit (IC) device, a designer first creates high-level behavior descriptions of the IC device using a hardware description language (HDL) such as Verilog and VHDL. As the complexity of the IC devices is growing exponentially due to changes such as shrinking in size of the IC chips and integration of more functionality onto a single IC chip, the behavioral descriptions of the devices are also becoming complex due to a large number of code blocks written in HDL for the IC chips.

In the field of RTL design and verification, it is common for errors or issues to arise in the written code blocks, which must be identified and resolved using specialized verification and debugging tools. However, verification and debugging tools face significant challenges when it comes to effectively reading and interpreting binary or hexadecimal values of single bit or multi-bit signals in a visual display of the RTL code blocks. Specifically, analyzing data packets or instructions becomes difficult to clearly identify and distinguish values due to complexity of multi-bit representations.

Separate disclosures provide a methodology for generating a data/control flow dependency graph of the underlying Register Transfer Level (RTL) code written in a Hardware Description Language (HDL). This methodology includes creating a visual representation of the graph. However, once this visual display is generated, challenges persist in interpreting binary or hexadecimal values on multibit signals to identify data packets or instructions. Furthermore, for wide buses, visually discerning differences in values between two buses, which may vary by only one or a few bits, can be particularly challenging.

Furthermore, for wide bus signals, which are commonly used in RTL designs, visually detecting even minor differences in values across two busses, where discrepancies may exist in only a single bit or a few bits, may become particularly challenging. The difficulty in pinpointing small variations between buses or signals in large-scale RTL code, hinders the efficiency of debugging and verification processes, leading to potential delays in the design cycle and a higher likelihood of overlooking critical errors.

Therefore, there is a need for more efficient and precise verification and debugging tools that can overcome the above-mentioned limitations and enable clearer, more accurately interpreting the binary or hexadecimal values of multi-bit signals in a visual display of the RTL code blocks.

The information disclosed in this background of the disclosure section is only for enhancement of understanding of the general background of the invention and should not be taken as an acknowledgement or any form of suggestion that this information forms the prior art already known to a person skilled in the art.

### SUMMARY

Disclosed herein is a verification and debugging tool for Register Transfer Level (RTL) code. The verification and debugging tool comprises an input interface configured to receive RTL code in a Hardware Description Language (HDL). Further, the verification and debugging tool comprises an RTL parser configured to parse the RTL code, and generate an abstract syntax tree representing the syntactic structure of the RTL code. Thereafter, the verification and debugging tool comprises a graph converter configured to convert the abstract syntax tree into an RTL directed graph. The RTL directed graph comprises a plurality of RTL code blocks represented as nodes and each node corresponding to a functional block of the RTL code. Furthermore, the verification and debugging tool comprises an assignment module configured to examine one or more signal values of the RTL code blocks, determine whether the signal value corresponds to an instruction or a data packet, assign an instruction mnemonic to the signal value when the signal represents an instruction, and assign a unique symbolic name to the signal value when the signal represents the data packet. Finally, the verification and debugging tool comprises a visual display configured to display the RTL directed graph along with the assigned instruction mnemonics and symbolic names.

Further, disclosed herein is a method of displaying mnemonics and symbolic names of signals in Register Transfer Level (RTL) code blocks. The method includes receiving RTL code in a Hardware Description Language (HDL). Further, the method includes parsing the RTL code, and generating an abstract syntax tree representing the syntactic structure of the RTL code. Thereafter, the method includes converting the abstract syntax tree into an RTL directed graph. The RTL directed graph comprises a plurality of RTL code blocks represented as nodes and each node corresponding to a functional block of the RTL code. Furthermore, the method includes examining one or more signal values of the RTL code blocks. Determining whether the signal value corresponds to an instruction or a data packet. Assigning an instruction mnemonic to the signal value when the signal represents an instruction. Assigning a unique symbolic name to the signal value when the signal represents the data packet. Finally, the method includes displaying the RTL directed graph along with the assigned instruction mnemonics and symbolic names.

Furthermore, the present disclosure relates to a non-transitory computer readable medium including instructions stored thereon that when processed by at least one processor, cause a verification and debugging tool to perform operations comprising receiving RTL code in a Hardware Description Language (HDL). Further, the instructions cause the processor to parse the RTL code, and generate an abstract syntax tree representing the syntactic structure of the RTL code. Thereafter, the instructions cause the processor to convert the abstract syntax tree into an RTL directed graph. The RTL directed graph comprises a plurality of RTL code blocks represented as nodes and each node corresponding to a functional block of the RTL code. Furthermore, the instructions cause the processor to examine one or more signal values of the RTL code blocks, determine whether the signal value corresponds to an instruction or a data packet, assign an instruction mnemonic to the signal value when the signal represents an instruction, and assign a unique symbolic name to the signal value when the signal represents the data packet. Finally, the instructions cause the processor to display the RTL directed graph along with the assigned instruction mnemonics and symbolic names.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE ACCOMPANYING DRAWINGS

The accompanying drawings, which are incorporated in and constitute a part of this disclosure, illustrate exemplary embodiments and, together with the description, explain the disclosed principles. In the figures, the left-most digit(s) of a reference number identifies the figure in which the reference number first appears. The same numbers are used throughout the figures to reference like features and components. Some embodiments of system and/or methods in accordance with embodiments of the present subject matter are now described, by way of example only, and regarding the accompanying figures, in which:

FIG. 1 shows an exemplary environment of displaying mnemonics and symbolic names of signals in Register Transfer Level (RTL) code blocks, in accordance with some embodiments of the present disclosure;

FIG. 2A shows an exemplary illustration of the symbolic names of the multibit signals in the RTL code blocks, in accordance with some embodiments of the present disclosure;

FIG. 2B shows an exemplary illustration of the mnemonics of the multibit signals in the RTL code blocks, in accordance with some embodiments of the present disclosure;

FIG. 3A shows a flowchart illustrating method of displaying mnemonics and symbolic names of signals in Register Transfer Level (RTL) code blocks, in accordance with some embodiments of the present disclosure;

FIG. 3B illustrates a flow diagram to assign mnemonics and symbolic names of multibit signals in RTL code blocks, in accordance with some embodiments of the present disclosure;

FIG. 4 illustrates a block diagram of an exemplary computer system for implementing embodiments consistent with the present disclosure.

It should be appreciated by those skilled in the art that any block diagrams herein represent conceptual views of illustrative systems embodying the principles of the present subject matter. Similarly, it will be appreciated that any flow charts, flow diagrams, state transition diagrams, pseudo code, and the like represent various processes which may be substantially represented in computer readable medium and executed by a computer or processor, whether such computer or processor is explicitly shown.

### DETAILED DESCRIPTION

In the present document, the word “exemplary” is used herein to mean “serving as an example, instance, or illustration.” Any embodiment or implementation of the present subject matter described herein as “exemplary” is not necessarily to be construed as preferred or advantageous over other embodiments.

While the disclosure is susceptible to various modifications and alternative forms, specific embodiment thereof has been shown by way of example in the drawings and will be described in detail below. It should be understood that it is not intended to limit the disclosure to the specific forms disclosed, but on the contrary, the disclosure is to cover all modifications, equivalents, and alternative falling within the scope of the disclosure.

The terms “comprises”, “comprising”, “includes”, or any other variations thereof, are intended to cover a non-exclusive inclusion, such that a setup, device, or method that comprises a list of components or steps does not include only those components or steps but may include other components or steps not expressly listed or inherent to such setup or device or method. In other words, one or more elements in a system or identity server proceeded by “comprises… a” does not, without more constraints, preclude the existence of other elements or additional elements in the system or method.

The terms like “at least one” and “one or more” may be used interchangeably throughout the description.

The terms like “verification and debugging tool”, “verification tool”, “debugging tool” and “tool” may be used interchangeably throughout the description.

The terms like “RTL code” and “code” may be used interchangeably throughout the description.

The terms like “circuit designer” and “designer” may be used interchangeably throughout the description.

The present disclosure relates to a verification and debugging tool that represents the Register Transfer Level (RTL) code blocks. The RTL code is a coding style used in digital system design and computer engineering, that is written using Hardware Description Language (HDL) like Verilog or VHDL. The RTL code defines the functioning of a digital circuit that may include multiple code blocks. In particular, RTL describes how the data transforms and flows from one register to another. The transformation of data is performed by combinational logic that exists between the registers. The operation of the RTL code is verified by using the verification tool and if any errors or problems arise in the code during its operation, verification engineer may use debugging tool to resolve the problems. The tool may convert the RTL code into an abstract syntax tree and then convert the abstract syntax tree into an RTL directed graph. The present disclosure describes the tool which provides the global visual view of all the code blocks of the RTL code in the form of the directed graph.

In an embodiment, the tool disclosed in the present disclosure provides a provision of assigning mnemonic or symbolic name to one or more objects in the global visual view of all the RTL code blocks. In the embodiment, the tool assigns a unique symbolic name for single or multibit signal values. The symbolic name is assigned to represent the binary or hexadecimal values for the single or multibit signal values in a particular timestep.

In the embodiment, the assignment of the symbolic name is used for the objects of the RTL block which represent data packets. The symbolic name is displayed next to the signal value instead of displaying the binary or hexadecimal values for the single or multibit signal values.

In an embodiment, the tool provides a provision of assigning the mnemonic to one or more objects in the global visual view of all the RTL code blocks. In the embodiment, the tool assigns the mnemonic for the instruction corresponding to the signal value. The mnemonic is assigned to represent the binary or hexadecimal values for the single or multibit signal values in the particular timestep.

In the embodiment, the assignment of the instruction mnemonic is displayed next to the signal value instead of displaying the binary or hexadecimal values for the single or multibit signal values.

In the embodiment, the assignment step helps in improving the readability of the signal values and providing accurate interpretation for the binary or hexadecimal values of the single or multi-bit signals in the global visual view of all the RTL code blocks.

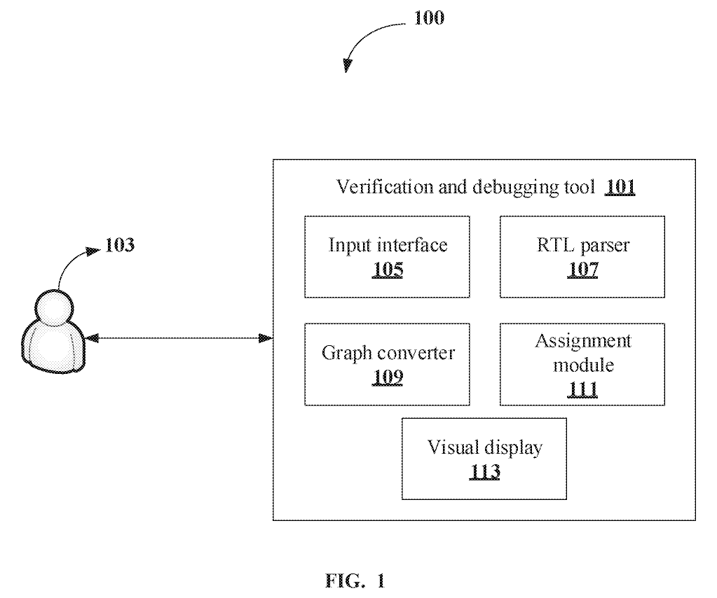

FIG. 1 shows an exemplary environment of displaying mnemonics and symbolic names of signals in Register Transfer Level (RTL) code blocks, in accordance with some embodiments of the present disclosure.

Exemplary environment 100 includes a verification and debugging tool 101 and a user 103. The verification and debugging tool 101 may include an input interface 105, an RTL parser 107, a graph converter 109, an assignment module 111 and a visual display 113. The user 103 may interact with the verification and debugging tool 101 using the input interface 105 and the visual display 113. The input interface 105 may include, without limitation, keyboards, mouse, touchscreens, and the like, which allow direct user interaction. The input interface 105 may also receive input from any sources provided by the user 103. As an example, the input interface 105 may receive input from Uniform Resource Locator (URL). The output may be displayed on the visual display 113. As an example, the visual display 113 may include, without limitation, an electronic screen, a touchscreen and the like, which allows display of the output. In an embodiment, the verification and debugging tool 101 may be a computing device. As an example, the computing device may be any device used by the user 103 such as, but not limited to, mobile phones, smartphones, laptops, and Personal Computers (PCs). In some embodiments, the verification and debugging tool 101 may be configured within the computing device (not shown in figure).

In an embodiment, the input interface 105 may be configured to receive RTL code in a Hardware Description Language (HDL) from the user 103. The HDLs may include, without limitation, at least one of Verilog and VHSIC Hardware Description Language (VHDL). As an example, the user 103 may be a circuit designer. The RTL code may describe behavior and component connections of a circuit such as an Integrated Circuit (IC). The RTL code may include one or more code blocks describing the operations of one or more entities/components of the circuit. In an embodiment, the input interface 105 may be further configured to validate syntax of the RTL code. If syntax error is detected, the syntax error may be displayed on the visual display 113 allowing the user 103 to edit the RTL code to rectify the syntax error. The input interface 105 may also detect any error which may affect execution of the RTL code.

In an embodiment, upon receiving the RTL code, the RTL parser 107 may be configured to parse the RTL code. In an embodiment, the RTL parser 107 may parse the RTL code by performing lexical and syntactic analysis to identify structural elements such as modules, signals, assignments, and control statements. Based on this analysis, the RTL parser 107 may generate an Abstract Syntax Tree (AST) that represents the hierarchical syntactic structure of the RTL code. The AST may include nodes corresponding to language constructs and captures parent-child relationships between statements, thereby providing a structured and unambiguous representation of the RTL code for subsequent transformation into an RTL directed graph.

In an embodiment, upon generating the AST, the graph converter 109 may be configured to convert the AST into the RTL directed graph. The RTL directed graph may include a plurality of RTL code blocks represented as nodes and each node corresponding to a functional block of the RTL code. The graph converter 109 may be further configured to represent signals of the RTL code as vertices of the RTL directed graph. The graph converter 109 may also provide one or more customizable display options for the RTL directed graph. The customizable options may enable the user 103 to modify the visual representation of the RTL directed graph to suit specific debugging or analysis requirements. The one or more customizable display options may include, without limitation, color coding for different signal types or logic states, adjustable node sizes to emphasize critical modules, selectable layers for viewing control flow or data flow independently, and variable line thickness or styles to indicate signal width or type. Additional customization may include zoom functionality for detailed inspection of individual nodes, dynamic visual effects to represent changes in signal values over time, and grouping of related nodes into functional sections. These customizable display options enhance clarity, improve navigation within complex RTL designs, and facilitate efficient identification of design issues during verification and debugging. In some embodiments, the RTL directed graph may be configured to display at least one of control flow and data flow. At least one of the control flow and the data flow may be displayed in a visually distinguishable manner. The visual distinction between the control flow and the data flow may be obtained using one of different arrow styles or different colors. In other words, the visual distinction between control flow and data flow within the RTL directed graph is achieved through the use of differentiated graphical indicators. In one embodiment, the distinction is provided by employing different arrow styles, such as solid arrows for data flow and dashed arrows for control flow, or by varying arrowhead shapes to represent signal types. Alternatively, the distinction may be implemented using different colors for the respective flows, enabling clear and intuitive identification of control signals versus data paths. These visual differentiation techniques enhance the readability of complex RTL designs and facilitate efficient debugging and verification by allowing users to quickly interpret the nature of each connection within the graph.

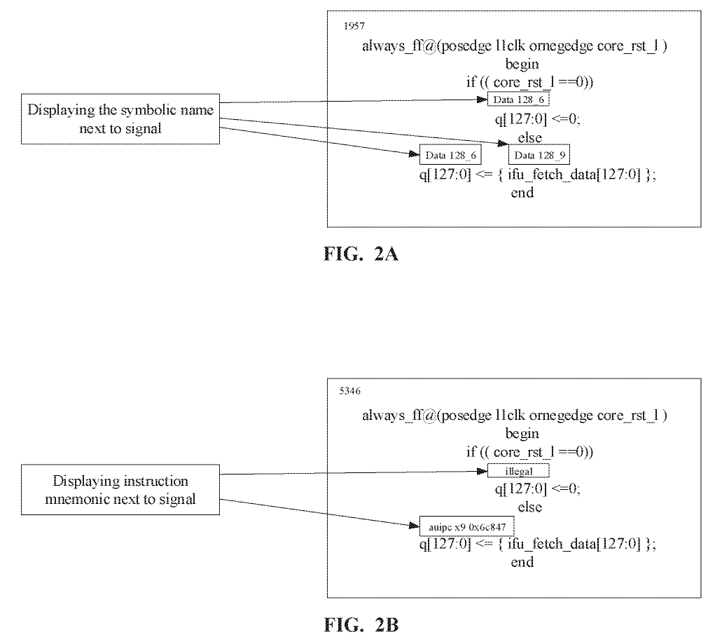

In an embodiment, upon converting the AST into the RTL directed graph, the assignment module 111 may be configured to examine one or more signal values of the RTL code blocks. The assignment module 111 may be configured to perform semantic enrichment of signal values within the RTL directed graph by analyzing one or more signals associated with RTL code blocks at specific timesteps to determine whether each signal represents an instruction or a data packet. When the signal corresponds to an instruction, the module assigns a human‑readable instruction mnemonic that reflects the underlying binary or hexadecimal representation, aiding quick interpretation during verification and debugging. For signals that represent data packets, the module assigns a unique symbolic name that abstracts single‑ or multi‑bit values (binary or hexadecimal) at the relevant timestep, improving clarity and traceability across the graph. The assigned mnemonics and symbolic names are rendered adjacent to their corresponding signal values within the visual display, ensuring users can navigate between global and detailed views while preserving context during debugging. The RTL parser 107 and the graph converter 109 may be configured to represent signals as vertices and flylines to indicate fan-in and fan-out connections between RTL code blocks. Exemplary illustrations are provided in FIG. 2A and 2B.

In an embodiment, upon storing the node block structures, the visual display 113 may be configured to display the RTL directed graph along with the assigned instruction mnemonics and symbolic names. The visual display 113 may display the RTL directed graph along with the assigned instruction mnemonics and symbolic names adjacent to corresponding signal values. The visual display 113 may also include an output interface configured to display debug information related to RTL code analysis and results (not shown in figure). In some embodiments, the visual display 113 and the output interface may be same. The visual display 113 and the output interface may also display results in a graphical format. In an embodiment, the visual display 113 may be configured to support zoom functionality for viewing details of individual code blocks or nodes. The zoom functionality may allow the user 103 to focus on specific areas of the RTL directed graph while preserving the ability to return to an overall view. The visual display 113 may also include user interface which may allow the user interactions within the visual display 113. The user interface may allow the user 103 to group multiple code blocks into functional sections. The visual display 113 provides an integrated environment for real-time analysis and debugging of RTL designs. By providing contextual labeling of signals through instruction mnemonics and symbolic names, the verification and debugging tool 101 enhances interpretability of RTL graphs and reduces ambiguity during debugging. This capability enables engineers to quickly distinguish between control and data flows, improving traceability and comprehension of design behavior. As a result, verification workflows become more efficient, accelerating error localization and minimizing the time required to identify and resolve functional issues.

FIG. 2A shows an exemplary illustration of the symbolic names of the multibit signals in the RTL code blocks, in accordance with an embodiment of the present disclosure. In the exemplary embodiment, a code block id ‘1957’ has the symbolic name ‘Data_128_9’ which may be assigned to the data packet and may be displayed next to the signal value. The binary value of the data packet of the signal is ‘11110000000000000000 00000001000000000000 00000110000000000000 00000000000000000000 00000000111100000000 00000000011000001000 00110001’. Such value is not displayed, rather the symbolic name ‘Data_128_9’ may be displayed for this binary value.

FIG. 2B shows an exemplary illustration of the mnemonics of the multibit signals in the RTL code blocks, in accordance with an embodiment of the present disclosure. In the exemplary embodiment, the code block id ‘5346’ has the instruction mnemonic ‘auipc x9 0x6c847’ which may be assigned to the instruction and may be displayed next to the signal value. The binary value of the instruction of the signal is ‘01101100100001000111010010010111’. Such value is not displayed, rather the instruction mnemonic ‘auipc x9 0x6c847’ may be displayed for this binary value.

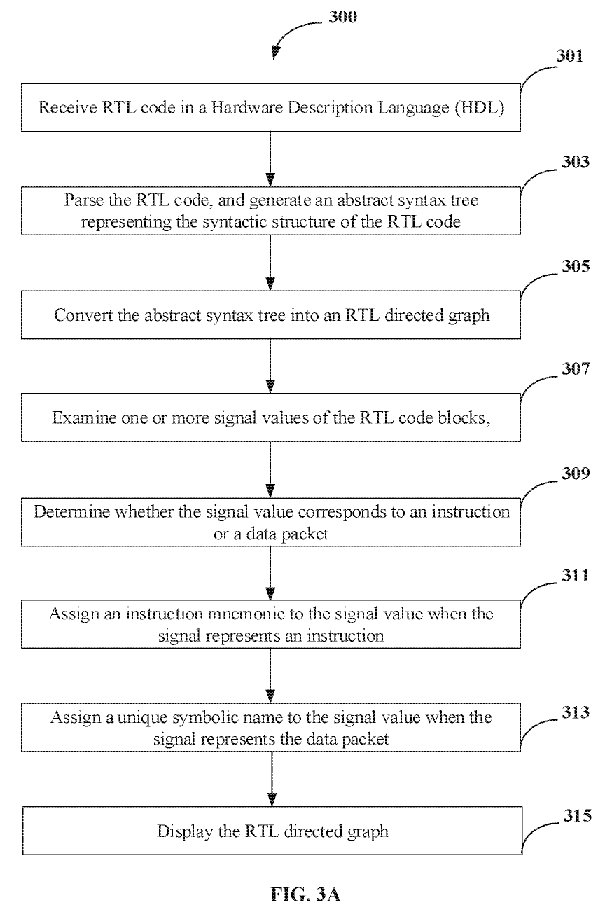

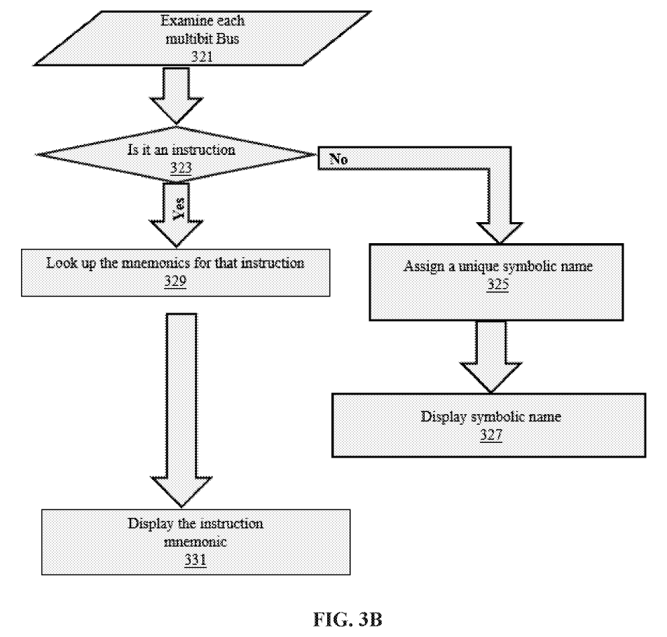

FIG. 3A is a flowchart illustrating a method of displaying mnemonics and symbolic names of signals in Register Transfer Level (RTL) code blocks, in accordance with some embodiments of the present disclosure.

As illustrated in FIG. 3A, the method 300 may include one or more blocks illustrating a method of displaying mnemonics and symbolic names of signals in Register Transfer Level (RTL) code blocks, using the verification and debugging tool 101 illustrated in FIG. 1. The method 300 may be described in the general context of computer executable instructions. Generally, computer executable instructions can include routines, programs, objects, components, data structures, procedures, modules, and functions, which perform specific functions or implement specific abstract data types.

The order in which the method 300 is described is not intended to be construed as a limitation, and any number of the described method blocks can be combined in any order to implement the method. Additionally, individual blocks may be deleted from the methods without departing from the scope of the subject matter described herein. Furthermore, the method can be implemented in any suitable hardware, software, firmware, or combination thereof.

At block 301, the method 300 includes receiving, by a processor of the verification and debugging tool 101, RTL code in a Hardware Description Language (HDL). The HDLs may include at least one of Verilog and VHSIC Hardware Description Language (VHDL). Further, the processor may validate syntax of the RTL code.

At block 303, the method 300 includes parsing, by the processor, the RTL code, and generating an abstract syntax tree representing the syntactic structure of the RTL code.

At block 305, the method 300 includes converting, by the processor, the abstract syntax tree into an RTL directed graph. The RTL directed graph may include a plurality of RTL code blocks represented as nodes and each node corresponding to a functional block of the RTL code. The processor may represent signals as vertices and flylines to indicate fan-in and fan-out connections between RTL code blocks. Further, the processor may provide one or more customizable display options for the RTL directed graph. The processor may support zoom functionality for viewing details of individual code blocks or nodes. The zoom functionality may allow a user 103 to focus on specific areas of the RTL directed graph while preserving ability to return to an overall view. The RTL directed graph may be configured to display least one of control flow and data flow, wherein the at least one of the control flow and the data flow is displayed in a visually distinguishable manner.

At block 307, the method 300 includes examining, by the processor, one or more signal values of the RTL code blocks.

At block 309, the method 300 includes determining, by the processor, whether the signal value corresponds to an instruction or a data packet.

At block 311, the method 300 includes assigning, by the processor, an instruction mnemonic to the signal value when the signal represents an instruction. The instruction mnemonic may be assigned to represent the binary or hexadecimal values of the single or multibit signals corresponding to instructions at a particular timestep.

At block 313, the method 300 includes assigning, by the processor, a unique symbolic name to the signal value when the signal represents the data packet. The unique symbolic name may be assigned to represent the binary or hexadecimal values of the single or multibit signals at a particular timestep.

At block 315, the method 300 includes displaying, by the processor, the RTL directed graph along with the assigned instruction mnemonics and symbolic names. The processor may configure the visual display 113 to display a global visual view of all RTL code blocks in the form of a directed graph, enabling hierarchical representation of RTL blocks. The unique symbolic name or instruction mnemonic may be displayed next to the signal value. The assigned instruction mnemonics and symbolic names may be displayed adjacent to corresponding signal values. The processor may configure the visual display 113 to support zoom functionality for viewing details of individual code blocks or nodes. The zoom functionality may allow the user 103 to focus on specific areas of the RTL directed graph while preserving the ability to return to an overall view.

FIG. 3B illustrates a flow diagram to assign mnemonics and symbolic names of multibit signals in RTL code blocks, in accordance with some embodiments of the present disclosure.

At step 321, the verification and debugging tool 101 may examine single or multibit bus/signal value of one or more objects in the global visual view of all the RTL code blocks.

At step 323, the verification and debugging tool 101 may determine whether an object among the one or more objects present in the signals of the RTL code blocks is the instruction or the data packet.

At step 325, after the determination that the object in the signal is not the instruction, the assignment module 111 may assign the unique symbolic name for single or multibit signal values. The symbolic name is assigned to represent the binary or hexadecimal values for the single or multibit signal values in a particular timestep.

In the embodiment, the assignment module 111 may be used to assign the symbolic name for the objects of the RTL block which represent data packets.

At step 327, the assignment module 111 may display the symbolic name next to the signal value, instead of displaying the binary or hexadecimal values for the single or multibit signal values.

At step 329, after the determination that the object in the signal is the instruction, the assignment module 111 may look up for the mnemonic corresponding to the signal value of the instruction.

In the embodiment, after finding the mnemonic corresponding to the signal value of the instruction, the assignment module 111 may assign the mnemonic to that instruction. The instruction mnemonic is assigned to represent the binary or hexadecimal values for the single or multibit signal values in a particular timestep.

At step 331, the assignment module 111 may display the instruction mnemonic next to the signal value instead of displaying the binary or hexadecimal values for the single or multibit signal values.

### Computer System

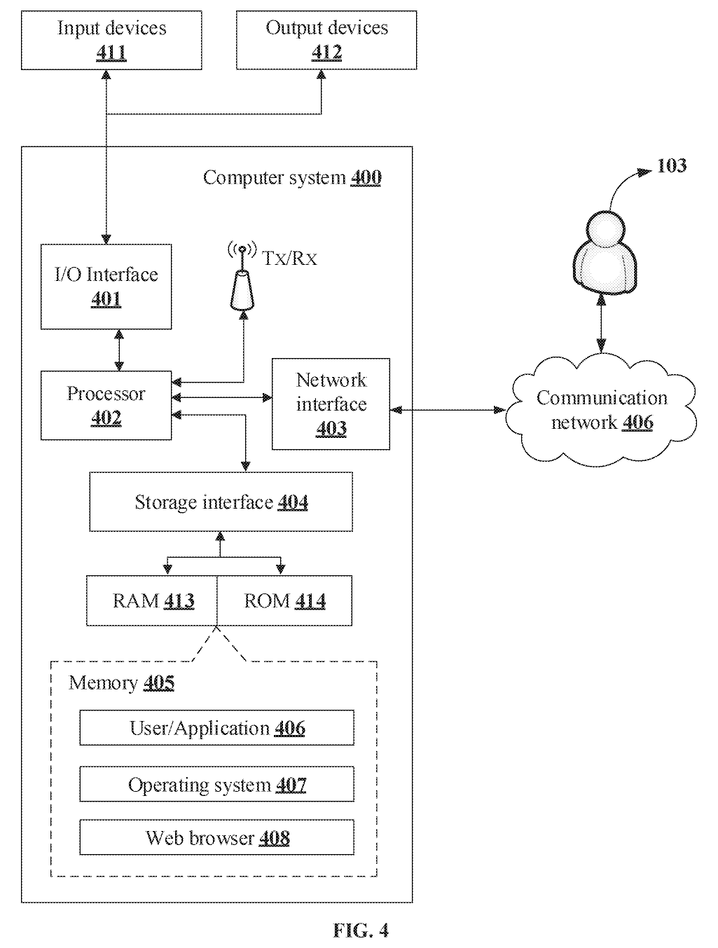

FIG. 4 illustrates a block diagram of an exemplary computer system 400 for implementing embodiments consistent with the present disclosure. In an embodiment, the computer system 400 may be a verification and debugging tool 101 illustrated in FIG. 1. The computer system 400 may include a central processing unit (“CPU” or “processor” or “memory controller”) 402. The processor 40 2 may comprise at least one data processor for executing program components for executing user- or system-generated business processes. A user may include a network manager, an application developer, a programmer, an organization, or any system/sub-system being operated parallelly to the computer system 400. The processor 402 may include specialized processing units such as integrated system (bus) controllers, memory controllers/memory management control units, floating point units, graphics processing units, digital signal processing units, etc.

The processor 402 may be disposed in communication with one or more Input/Output (I/O) devices (41 1 and 41 2) via I/O interface 401. The I/O interface 40 1 may employ communication protocols/methods such as, without limitation, audio, analog, digital, stereo, IEEE^{®}-1394, serial bus, Universal Serial Bus (USB), infrared, PS/2, BNC, coaxial, component, composite, Digital Visual Interface (DVI), high-definition multimedia interface (HDMI), Radio Frequency (RF) antennas, S-Video, Video Graphics Array (VGA), IEEE^{®} 802.n /b/g/n/x, Bluetooth, cellular (e.g., Code-Division Multiple Access (CDMA), High-Speed Packet Access (HSPA+), Global System For Mobile Communications (GSM), Long-Term Evolution (LTE) or the like), etc. Using the I/O interface 401, the computer system 400 may communicate with one or more I/O devices 411 and 412.

In some embodiments, the processor 402 may be disposed in communication with a network 409 via a network interface 403. The network interface 403 may communicate with the network 409. The network interface 40 3 may employ connection protocols including, without limitation, direct connect, Ethernet (e.g., twisted pair 10/100/1000 Base T), Transmission Control Protocol/Internet Protocol (TCP/IP), token ring, IEEE^{®} 802.11a/b/g/n/x, etc.

In an implementation, the preferred network 409 may be implemented as one of the several types of networks, such as intranet or Local Area Network (LAN) and such within the organization. The preferred network 409 may either be a dedicated network or a shared network, which represents an association of several types of networks that use a variety of protocols, for example, Hypertext Transfer Protocol (HTTP), Transmission Control Protocol/Internet Protocol (TCP/IP), Wireless Application Protocol (WAP) etc., to communicate with each other. Further, the network 409 may include a variety of network devices, including routers, bridges, RAN nodes, computing devices, storage devices, etc. Using the network interface 403 and the network 409, the computer system 400 may communicate with a user 103.

In some embodiments, the processor 402 may be disposed in communication with a memory 405 (e.g., RAM 413, ROM 414, etc. as shown in FIG. 6) via a storage interface 404. The storage interface 404 may connect to memory 405 including, without limitation, memory drives, removable disc drives, etc., employing connection protocols such as Serial Advanced Technology Attachment (SATA), Integrated Drive Electronics (IDE), IEEE-1394, Universal Serial Bus (USB), fiber channel, Small Computer Systems Interface (SCSI), etc. The memory drives may further include a drum, magnetic disc drive, magneto-optical drive, optical drive, Redundant Array of Independent Discs (RAID), solid-state memory devices, solid-state drives, etc.

The memory 405 may store a collection of program or database components, including, without limitation, user/application interface 406, an operating system 407, a web browser 408, and the like. In some embodiments, computer system 400 may store user/application data 406, such as the data, variables, records, etc. as described in this invention. Such databases may be implemented as fault-tolerant, relational, scalable, secure databases such as Oracle^{®} or Sybase^{®}.

The operating system 407 may facilitate resource management and operation of the computer system 400. Examples of operating systems include, without limitation, APPLE^{®} MACINTOSH^{®} OS X^{®}, UNIX^{®}, UNIX-like system distributions (E.G., BERKELEY SOFTWARE DISTRIBUTION^{®} (BSD), FREEBSD^{®}, NETBSD^{®}, OPENBSD, etc.), LINUX^{®} DISTRIBUTIONS (E.G., RED HAT^{®}, UBUNTU^{®}, KUBUNTU^{®}, etc.), IBM^{®} OS/2^{®}, MICROSOFT^{®} WINDOWS^{®} (XP^{®}, VISTA^{®}/7/8, 10 etc.), APPLE^{®} IOS^{®}, GOOGLE ^{TM} ANDROID ^{TM}, BLACKBERRY^{®} OS, or the like.

The user interface 406 may facilitate display, execution, interaction, manipulation, or operation of program components through textual or graphical facilities. For example, the user interface 406 may provide computer interaction interface elements on a display system operatively connected to the computer system 400, such as cursors, icons, check boxes, menus, scrollers, windows, widgets, and the like. Further, Graphical User Interfaces (GUIs) may be employed, including, without limitation, APPLE^{®} MACINTOSH^{®} operating systems’ Aqua^{®}, IBM^{®} OS/2^{®}, MICROSOFT^{®} WINDOWS^{®} (e.g., Aero, Metro, etc.), web interface libraries (e.g., ActiveX^{®}, JAVA^{®}, JAVASCRIPT^{®}, AJAX, HTML, ADOBE^{®} FLASH^{®}, etc.), or the like.

The web browser 408 may be a hypertext viewing application. Secure web browsing may be provided using Secure Hypertext Transport Protocol (HTTPS), Secure Sockets Layer (SSL), Transport Layer Security (TLS), and the like. The web browsers 408 may utilize facilities such as AJAX, DHTML, ADOBE^{®} FLASH^{®}, JAVASCRIPT^{®}, JAVA^{®}, Application Programming Interfaces (APIs), and the like. Further, the computer system 400 may implement a mail RAN node stored program component. The mail RAN node may utilize facilities such as ASP, ACTIVEX^{®}, ANSI^{®} C++/C#, MICROSOFT^{®}, .NET, CGI SCRIPTS, JAVA^{®}, JAVASCRIPT^{®}, PERL^{®}, PHP, PYTHON^{®}, WEBOBJECTS^{®}, etc. The mail RAN node may utilize communication protocols such as Internet Message Access Protocol (IMAP), Messaging Application Programming Interface (MAPI), MICROSOFT^{®} exchange, Post Office Protocol (POP), Simple Mail Transfer Protocol (SMTP), or the like. In some embodiments, the computer system 40 0 may implement a mail client stored program component. The mail client may be a mail viewing application, such as APPLE^{®} MAIL, MICROSOFT^{®} ENTOURAGE^{®}, MICROSOFT^{®} OUTLOOK^{®}, MOZILLA^{®} THUNDERBIRD^{®}, and the like.

Furthermore, one or more computer-readable storage media may be utilized in implementing embodiments consistent with the present invention. A computer-readable storage medium refers to any type of physical memory on which information or data readable by a processor may be stored. Thus, a computer-readable storage medium may store instructions for execution by one or more processors, including instructions for causing the processor(s) to perform steps or stages consistent with the embodiments described herein. The term “computer-readable medium” should be understood to include tangible items and exclude carrier waves and transient signals, i.e., non-transitory. Examples include Random Access Memory (RAM), Read-Only Memory (ROM), volatile memory, nonvolatile memory, hard drives, Compact Disc (CD) ROMs, Digital Video Disc (DVDs), flash drives, disks, and any other known physical storage media.

In light of the technical advancements provided by the disclosed method, the claimed steps, as discussed above, are not routine, conventional, or not well-known aspects in the art, as the claimed steps provide the aforesaid solutions to the technical problems existing in the conventional technologies. Further, the claimed steps clearly bring an improvement in the functioning of the system itself, as the claimed steps provide a technical solution to a technical problem.

The terms "an embodiment", "embodiment", "embodiments", "the embodiment", "the embodiments", "one or more embodiments", "some embodiments", and "one embodiment" mean "one or more (but not all) embodiments of the invention(s)" unless expressly specified otherwise.

The terms "including", "comprising", “having” and variations thereof mean "including but not limited to", unless expressly specified otherwise.

The enumerated listing of items does not imply that any or all the items are mutually exclusive, unless expressly specified otherwise. The terms "a", "an" and "the" mean "one or more", unless expressly specified otherwise.

A description of an embodiment with several components in communication with each other does not imply that all such components are required. On the contrary, a variety of optional components are described to illustrate the wide variety of possible embodiments of the invention.

When a single device or article is described herein, it will be clear that more than one device/article (whether they cooperate) may be used in place of a single device/article. Similarly, where more than one device/article is described herein (whether they cooperate), it will be clear that a single device/article may be used in place of the more than one device/article or a different number of devices/articles may be used instead of the shown number of devices or programs. The functionality and/or features of a device may be alternatively embodied by one or more other devices which are not explicitly described as having such functionality/features. Thus, other embodiments of invention need not include the device itself.

Finally, the language used in the specification has been principally selected for readability and instructional purposes, and it may not have been selected to delineate or circumscribe the inventive subject matter. It is therefore intended that the scope of the invention be limited not by this detailed description, but rather by any claims that issue on an application based here on. Accordingly, the embodiments of the present invention are intended to be illustrative, but not limiting, of the scope of the invention, which is set forth in the following claims.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

1. A verification and debugging tool for Register Transfer Level (RTL) code, the verification and debugging tool comprising:
an input interface configured to receive RTL code in a Hardware Description Language (HDL);
an RTL parser configured to:
parse the RTL code, and
generate an abstract syntax tree;
a graph converter configured to convert the abstract syntax tree into an RTL directed graph, wherein the RTL directed graph comprises a plurality of RTL code blocks represented as nodes and each node corresponding to a functional block of the RTL code;
an assignment module configured to:
examine one or more signal values of the RTL code blocks,
determine whether the signal value corresponds to an instruction or a data packet,
assign an instruction mnemonic to the signal value when the signal represents an instruction, and
assign a unique symbolic name to the signal value when the signal represents the data packet;
a visual display configured to display the RTL directed graph along with the assigned instruction mnemonics and symbolic names.

2. The verification and debugging tool of claim 1, wherein the unique symbolic name is assigned to represent the binary or hexadecimal values of the single or multibit signals at a particular timestep.

3. The verification and debugging tool of claim 1, wherein the instruction mnemonic is assigned to represent the binary or hexadecimal values of the single or multibit signals corresponding to instructions at a particular timestep.

4. The verification and debugging tool of claim 1, wherein the visual display comprises a global visual view of all RTL code blocks in the form of a directed graph, enabling hierarchical representation of RTL blocks.

5. The verification and debugging tool of claim 1, wherein the assignment module is configured to display the unique symbolic name or instruction mnemonic next to the signal value.

6. The verification and debugging tool of claim 1, wherein the visual display is configured to display the RTL directed graph along with the assigned instruction mnemonics and symbolic names adjacent to corresponding signal values.

7. The verification and debugging tool of claim 1, wherein the RTL parser and the graph converter are configured to represent signals as vertices and flylines to indicate fan-in and fan-out connections between RTL code blocks.

8. The verification and debugging tool of claim 1, wherein the visual display is configured to support zoom functionality for viewing details of individual code blocks or nodes.

9. The verification and debugging tool of claim 7, wherein the zoom functionality allows a user to focus on specific areas of the RTL directed graph while preserving ability to return to an overall view.

10. The verification and debugging tool of claim 1, wherein the RTL directed graph is configured to display at least one of control flow and data flow, wherein the at least one of the control flow and the data flow is displayed in a visually distinguishable manner.

11. A method of displaying mnemonics and symbolic names of signals in Register Transfer Level (RTL) code blocks, the method comprising:
receiving RTL code in a Hardware Description Language (HDL);
parsing the RTL code, and generating an abstract syntax tree representing the syntactic structure of the RTL code;
converting the abstract syntax tree into an RTL directed graph, wherein the RTL directed graph comprises a plurality of RTL code blocks represented as nodes and each node corresponding to a functional block of the RTL code;
examining one or more signal values of the RTL code blocks;
determining whether the signal value corresponds to an instruction or a data packet;
assigning an instruction mnemonic to the signal value when the signal represents an instruction;
assigning a unique symbolic name to the signal value when the signal represents the data packet; and
displaying the RTL directed graph along with the assigned instruction mnemonics and symbolic names.

12. A non-transitory computer readable medium including instructions stored thereon that when processed by at least one processor, cause a verification and debugging tool to perform operations comprising:
receiving RTL code in a Hardware Description Language (HDL);
parsing the RTL code, and generating an abstract syntax tree representing the syntactic structure of the RTL code;
converting the abstract syntax tree into an RTL directed graph, wherein the RTL directed graph comprises a plurality of RTL code blocks represented as nodes and each node corresponding to a functional block of the RTL code;
examining one or more signal values of the RTL code blocks;
determining whether the signal value corresponds to an instruction or a data packet;
assigning an instruction mnemonic to the signal value when the signal represents an instruction;
assigning a unique symbolic name to the signal value when the signal represents the data packet; and
displaying the RTL directed graph along with the assigned instruction mnemonics and symbolic names.
